(19) United States
(12) Patent Application Publication
(10) Pub. No.: US 2003/0116089 A1
(43) Pub. Date: Jun. 26, 2003

(54) Plasma implantation system and method with target movement

(76) Inventor: Steven R. Walther, Andover, MA (US)

Correspondence Address: Gary Loser, Varian Semiconductor Equipment Associates, Inc., 35 Dory Road, Gloucester, MA, 01930, US

(21) Appl. No.: 10/198,370

(22) Filed: Jul. 18, 2002

Related U.S. Application Data
(63) Continuation-in-part of application No. 10/006,462, filed on Dec. 4, 2001.

(51) Int. Cl. C23C 16/00

(52) U.S. Cl. 118/723 E

(57) ABSTRACT

A plasma implantation system and method implants ions from a plasma in a semiconductor substrate while the substrate is at two or more different positions. The semiconductor substrate may be moved during implantation processing, e.g., to help compensate for non-uniformities in the dose delivered to the substrate. In addition, only a portion of a substrate may be implanted during a portion of an implantation process for the substrate. A plurality of substrates may be simultaneously implantation processed in a same plasma implantation chamber, thereby potentially reducing implantation processing times.

### RELATED APPLICATIONS

This application claims the benefit under 35 USC §120 of U.S. application Ser. No. 10/006,462, filed Dec. 4, 2001. U.S. application Ser. No. 10/006,462 is hereby incorporated by reference in its entirety.

### FIELD OF THE INVENTION

This invention relates to implanting ions in materials, such as semiconductor wafers, in a plasma implantation system.

### BACKGROUND OF THE INVENTION

Ion implantation is a standard technique for introducing conductivity-altering impurities into semiconductor substrates, such as semiconductor wafers. Beamline ion implantation systems are commonly used to introduce such impurities into semiconductor wafers. In a conventional beamline ion implantation system, a desired impurity material is ionized, and the ions are accelerated to form an ion beam directed at a surface of the semiconductor wafer. Ions in the beam impacting the wafer penetrate into the semiconductor material to form a region of desired conductivity.

Beamline ion implantation systems operate efficiently for certain implantation conditions, such as when implanting ions at relatively high energies, but may not function as efficiently as desired for certain other applications. For example, as device features in semiconductor chips are made smaller to increase the device density on the chips, the width and depth of features formed by implanted ions must be reduced to accommodate the increased device density. Narrowing the width of features formed by implanted ions typically involves narrowing photoresist patterns or other masking features on the semiconductor wafer. However, decreasing the depth that ions are implanted into a semiconductor material to make shallower junctions or other features requires relatively lower implant energies. That is, implanted ions must have a lower kinetic energy when impacting the semiconductor to reduce the penetration depth of the ions. Although conventional beamline ion implantation systems operate efficiently at relatively higher implant energies, these systems may not operate efficiently at the lower energies required to obtain a shallow junction depth.

Plasma implantation systems have been used for implanting ions at relatively low energies into semiconductor wafers, e.g., to form relatively shallow junctions or other features in the semiconductor material. In one type of plasma implantation system, a semiconductor wafer is placed on a stationary conductive disk located in a plasma implantation chamber. An ionizable process gas that includes a desired dopant material is introduced into the chamber, and a voltage is applied to form a plasma in the vicinity of the semiconductor wafer. An electric field applied to the plasma causes ions in the plasma to be accelerated toward, and be implanted into, the semiconductor wafer. In some cases, plasma implantation systems have been found to operate efficiently at relatively low implant energies. Plasma implantation systems are described, for example, in U.S. Pat. No. 5,354,381 to Sheng, U.S. Pat. No. 6,020,592 to Liebert et al., and U.S. Pat. No. 6,182,604 to Goeckner et al.

In general, all implantation processes, whether beamline or plasma implantation, require an accurate total dose be provided to the wafer and that the dose across the wafer be highly uniform. These parameters are important because the total dose determines the electrical characteristics of the implanted region(s), while dose uniformity ensures that devices on the semiconductor wafer have operating characteristics within a desired range. Producing smaller feature sizes on a semiconductor wafer tends to heighten the already stringent requirements on total dose and dose uniformity because the smaller features are more sensitive to variations in the total dose and dose uniformity.

In a plasma implantation system, spatial dose uniformity may depend upon the uniformity of the plasma formed near the surface of the wafer and/or on electric fields present in the vicinity of the wafer during implantation. Since a plasma includes ions that move in sometimes random and unpredictable ways, over time, a plasma may have spatial non-uniformities that result in dose non-uniformity in the wafers being processed. Variations in electric fields generated near the wafer may also affect the dose uniformity by causing variations in the density of ions accelerated from the plasma into the wafer.

### SUMMARY OF THE INVENTION

In one aspect of the invention, the uniformity of particle implantation in a plasma implantation system may be improved by implanting ions into a semiconductor wafer when the wafer is at two or more different positions relative to the plasma or plasma discharge region. By moving the semiconductor wafer in at least some fashion during implantation processing, temporal and spatial variations in the plasma density, variations in electric fields in and around the plasma and near the wafer, and other parameters that affect dose uniformity may be averaged out or otherwise compensated for.

In one aspect of the invention, a plasma implantation system includes a plasma implantation chamber and a workpiece support that moves at least one workpiece within the plasma implantation chamber. A plasma generating device generates a plasma at or near a workpiece surface to implant ions in the workpiece, and a controller causes the workpiece support to move the workpiece in the chamber during an implantation process during which the controller causes the plasma generating device to generate a plasma and implant ions in the workpiece. A system in accordance with this aspect of the invention may provide more uniform implantation of a workpiece, such as a semiconductor wafer, by implanting the workpiece with ions from a plasma while the workpiece is moved and/or by otherwise positioning the workpiece at two or more different positions relative to a plasma or plasma discharge region during implantation. A system in accordance with this aspect of the invention also may provide shorter per workpiece implantation processing times because multiple workpieces may be positioned within an implantation chamber and simultaneously processed to implant ions in the workpieces.

In one aspect of the invention, the workpiece support includes a disk that is mounted for rotation in the plasma implantation chamber. A plurality of workpieces, such as semiconductor wafers, may be mounted to the disk and moved in a circular path in the plasma implantation chamber. Rotary motion of the workpieces may periodically present each of the workpieces to a plasma discharge region where ions from a plasma are implanted in the workpieces. Movement of the workpieces may be adjusted to help control dose uniformity and/or a total dose delivered to the workpieces.

In another aspect of the invention, a method for implanting ions in workpieces includes providing a plurality of workpieces in a plasma implantation chamber, moving the plurality of workpieces in the plasma implantation chamber, and implanting ions from a plasma located at or near a surface of at least one of the plurality of workpieces into the workpiece while the workpiece moves in the plasma implantation chamber.

In another aspect of the invention, a method for implanting ions in a workpiece includes providing at least one workpiece in a plasma implantation chamber and generating a plasma in a plasma discharge region located at or near a surface of the at least one workpiece in the plasma implantation chamber. Ions are implanted from the plasma in the at least one workpiece while the workpiece is in a first position relative to the plasma discharge region. The at least one workpiece is moved relative to the plasma discharge region, and ions are implanted from the plasma in the at least one workpiece while the workpiece is in a second position relative to the plasma discharge region.

In another aspect of the invention, a method for implanting ions in a semiconductor wafer includes providing at least one semiconductor wafer in a plasma implantation chamber. The at least one semiconductor wafer has a particle implantation area where ions are to be implanted. Although not necessary, the particle implantation area typically is one entire surface of the semiconductor wafer. A plasma is generated in the chamber and ions in the plasma are implanted in the at least one semiconductor wafer in an area that is smaller than the particle implantation area of the wafer. According to this aspect of the invention, portions of a semiconductor wafer may be implanted with ions in a plasma in a piecemeal fashion. By implanting only portions of the wafer at a given time, the implantation sub-areas on the wafer may be overlapped or otherwise arranged to compensate for non-uniformities in the implantation process, or to create desired non-uniformities in the implanted wafer.

These and other aspects of the invention will be apparent and/or obvious from the following description.

### BRIEF DESCRIPTION OF THE DRAWINGS

Aspects of the invention are described below in connection with the following drawings in which like reference numerals refer to like elements, and wherein:

FIG. 1 is a schematic block diagram of a plasma implantation system in accordance with an embodiment of the invention;

FIG. 2 is a perspective view of an exemplary workpiece support and plasma generating device in accordance with the invention;

FIG. 3 is a schematic diagram of a plasma implantation system having a rotating platen that supports a semiconductor wafer; and

FIG. 4 shows an illustrative arrangement in which portions of a semiconductor wafer are implanted.

### DETAILED DESCRIPTION

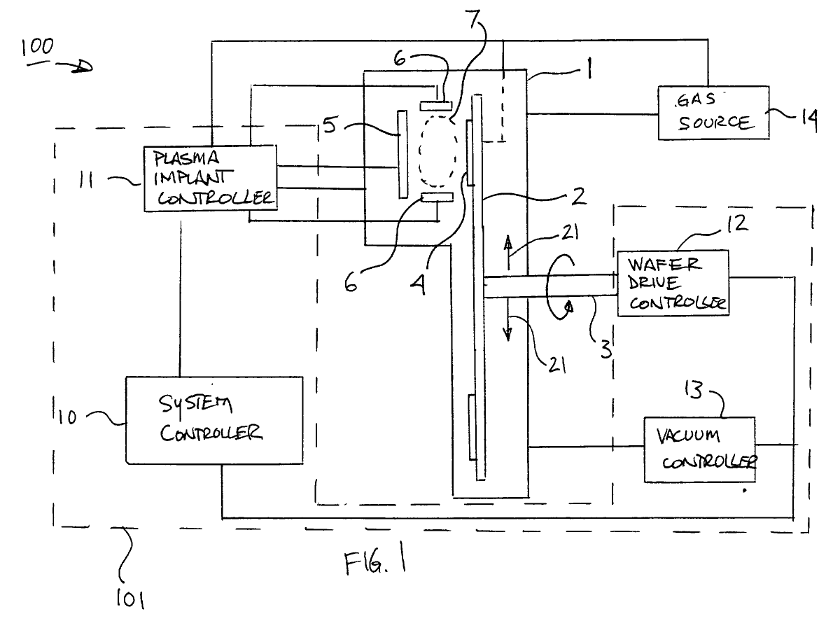

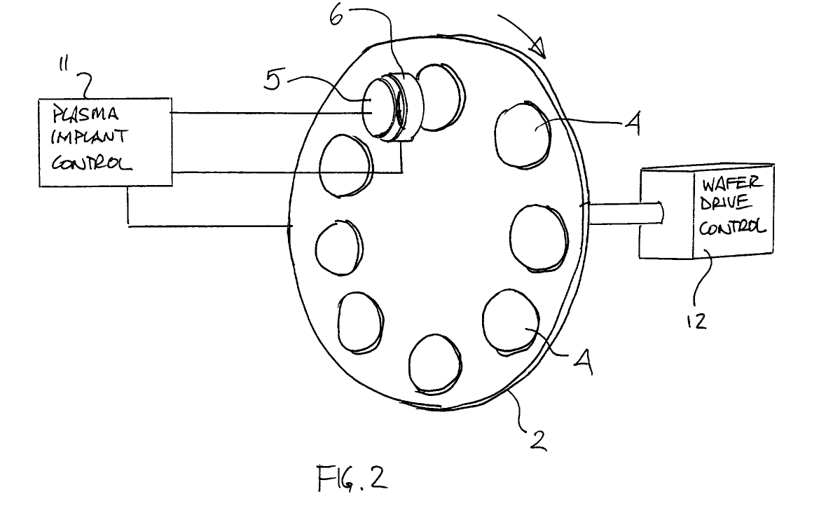

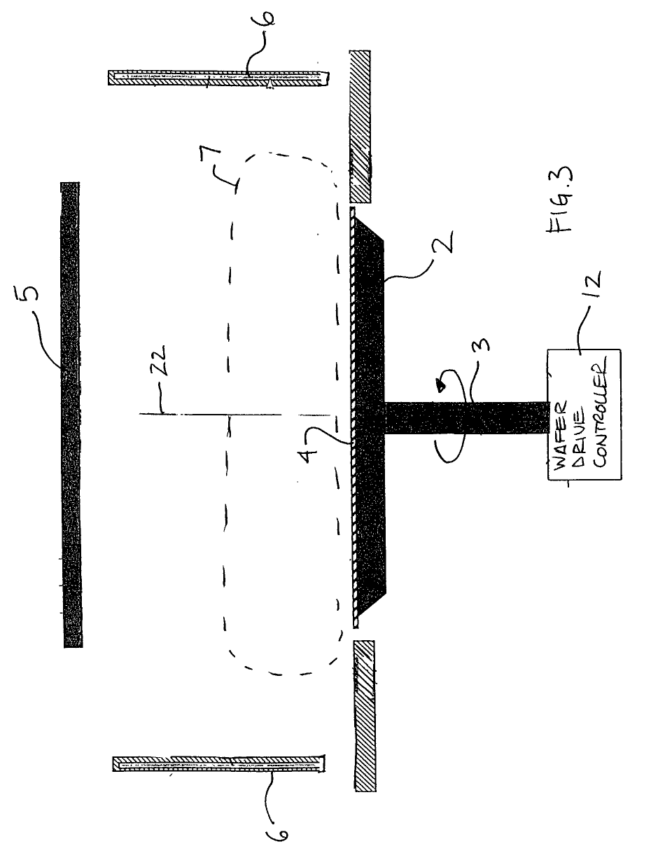

FIG. 1 is a schematic block diagram of a plasma implantation system in an illustrative embodiment of the invention, and FIGS. 2 and 3 show exemplary workpiece supports and plasma generating devices. Although various aspects of the invention are described with reference to FIGS. 1-3, the various aspects of the invention are not limited to the particular embodiments shown in FIGS. 1-3. Instead, aspects of the invention may be used in any suitable plasma implantation system having any suitable arrangement of components. Further, although some aspects of the invention are directed to achieving higher uniformity of implanted ions in a plasma system, these aspects of the invention may be combined with other uniformity enhancing arrangements, such as those described in U.S. Pat. No. 5,711,812, or combined with other plasma implantation system features that are known in the art, but not described in detail herein. For example, the plasma implantation system may be a pulsed system in which a plasma is subjected to a pulsed electric field to implant ions in a semiconductor wafer, or a continuous system in which a plasma is subjected to an approximately constant electric field. In short, aspects of the invention may be used in any suitable plasma implantation system in any suitable way.

In the illustrative embodiment of FIG. 1, a plasma implantation system 100 includes a plasma implantation chamber 1 within which semiconductor wafers 4 may be positioned and implanted with ions from a plasma. The term “ions” as used herein is intended to include the various particles implanted in a wafer during an implantation process. Such particles may include positively or negatively charged atoms or molecules, neutrals, contaminants, etc. In this embodiment, the wafers 4 may be mounted to a workpiece support 2 that is arranged to move the wafers 4 in the plasma implantation chamber 1 under the control of a wafer drive controller 12. Once the wafers 4 are suitably positioned in the plasma implantation chamber 1, a vacuum controller 13 may create a controlled low pressure environment in the chamber 1 suitable for implantation, and the wafers may be implanted with ions from a plasma generated in a plasma discharge region 7. The plasma may be generated in any suitable way by any suitable plasma generating device in any suitably sized or shaped plasma discharge region 7. In this illustrative embodiment, a plasma generating device includes an electrode 5 (commonly an anode) and a hollow pulse source 6 (commonly a cathode pulse source). Operation of the plasma generating device, including the gas source 14 may be controlled by a plasma implant controller 11. For example, the plasma implant controller 11 may communicate with the housing of the plasma implantation chamber 1, the workpiece support 2, electrode 5, hollow pulse source 6, the gas source 14 and other components to provide a suitable source of ionizable gas and electric fields to generate a suitable plasma and implant ions in the semiconductor wafers 4 as well as perform other desired functions. In this embodiment, the plasma generating device generates a plasma by exposing a gas provided by the gas source 14 containing desired dopant materials to an electric field established by the hollow pulse source 6. Ions in the plasma may be accelerated toward and implanted into the semiconductor wafer 4 by an electric field established between the electrode 5 and the workpiece support 2/semiconductor wafer 4. Additional details regarding such a plasma generating device are provided in U.S. Pat. No. 6,182,604 and U.S. application Ser. No. 10/006,462, which are both hereby incorporated by reference in their entirety.

Overall, system-level control of the plasma implantation system 100 may be performed by a system controller 10 which may provide control signals to the associated plasma implant controller 11, wafer drive controller 12 and vacuum controller 13 as well as other suitable systems for performing the desired input/output or other control functions. Thus, the system controller 10, the plasma implant controller 11, the wafer drive controller 12 and the vacuum controller 13 together form a controller 101 that controls the operation of the plasma implantation system 100. The controller 101 may include a general purpose data processing system, which can be a general purpose computer, or network of general purpose computers, and other associated devices, including communications devices, modems, and/or other circuitry or components necessary to perform the desired input/output or other functions. The controller 101 can also be implemented, at least in part, as a single special purpose integrated circuit (e.g., ASIC) or an array of ASICs, each having a main or central processor section for overall, system-level control, and separate sections dedicated to performing various different specific computations, functions and other processes under the control of the central processor section. The controller 101 can also be implemented using a plurality of separate dedicated programmable integrated or other electronic circuits or devices, e.g., hard wired electronic or logic circuits such as discrete element circuits or programmable logic devices. The controller 101 can also include any other components or devices, such as user input/output devices (monitors, displays, printers, a keyboard, a user pointing device, touch screen, etc.), drive motors, linkages, valve controllers, robotic devices, vacuum and other pumps, pressure sensors, ion detectors, power supplies, pulse sources, and so on. The controller 101 may also control operation of other portions of the system 100, such as automated, robotic wafer handling systems, load lock devices, vacuum valves and seals, etc. (not shown) to perform other suitable functions as is well known in the art, but not described in detail herein.

In accordance with one aspect of the invention, a semiconductor substrate may be implanted with ions from a plasma while the semiconductor substrate is in two or more different positions relative to the plasma or a plasma discharge region. Thus, in accordance with this aspect of the invention, a semiconductor wafer may be located in a first position and ions from a plasma implanted in the wafer, then the semiconductor wafer is moved to a second position where ions from the plasma again are implanted into the wafer. For example, the semiconductor substrate may be moved during the implantation process so the substrate moves between two different positions while ions are actually being implanted in the substrate. Alternately, the semiconductor substrate may be at rest at two or more different positions relative to the plasma discharge region or plasma when implanted with ions from a plasma. In another embodiment, the semiconductor substrate may be in motion relative to the plasma or plasma discharge region when implantation is initiated, but due to a short time during which ions actually impact the substrate (e.g., because of pulsing of the plasma with an electric field), the substrate may not move an appreciable distance during the time that ions actually impact the substrate. In this embodiment, implantation processing may include multiple, short duration implantation cycles during which ions are implanted in the substrate. As discussed above, moving a semiconductor substrate during implantation processing may compensate for non-uniformities in the implantation due to spatial and/or temporal variations in the plasma, variations in the electric fields present near the semiconductor substrate during implantation, and/or other parameters which affect implantation uniformity.

In the illustrative embodiment of FIG. 1, a semiconductor wafer 4 may be mounted to the workpiece support 2 and moved relative to the plasma or plasma discharge region 7 in any suitable way. For example, as shown in FIG. 2, the workpiece support 2 may include a disk on which a plurality of wafers 4 (e.g., 10 or more wafers 4) are mounted in a circular or other array. Alternately, one or more wafers 4 may be mounted to a workpiece support 2 having a different arrangement than the disk shown. The wafers 4 may be mounted to the workpiece support 2 by an electrostatic, centrifugal or mechanical chuck or by other means. In addition, the semiconductor wafers 4 may electrically communicate with at least a portion of the workpiece support 2, e.g., so that an appropriate electric field may be generated to implant ions in the plasma into the semiconductor wafer 4. Semiconductor wafer mounting arrangements for workpiece supports, such as a rotating disk used in conventional beamline ion implantation systems are well known to those of skill in the art. Thus, details regarding the variety of suitable wafer mounting systems are not provided herein.

The workpiece support 2 may be driven to rotate by a shaft 3 coupled to a wafer drive controller 12 which may include a servo drive motor that rotates the workpiece support 2 at a desired rate. As the wafers 4 are rotated or otherwise moved in the plasma implantation chamber 1, the wafers 4 may be periodically presented to the plasma for implantation, i.e., the wafers 4 may be suitably positioned relative to the plasma for implantation. Alternately, or in addition to rotary movement, the wafer drive controller 12 may move the wafer 4 in a radial direction relative to the disk rotation as shown by the up and down oriented arrows 21. As a result, the semiconductor wafer 4 may be moved in a circular path within the plasma implantation chamber 1 so that the wafer 4 moves in an arcuate trajectory relative to the plasma or plasma discharge region 7, as well as being moved in a linear (e.g., radial) direction relative to the plasma or plasma discharge region 7. Other suitable movement of the wafer 4 is contemplated, including tilting, pivoting or other movement of the wafer 4 on the workpiece support 2 or otherwise relative to the plasma discharge region 7. Likewise, the wafer may be moved along one or more linear paths in one or two dimensions.

In other embodiments, a wafer 4 may be moved so that it is continuously presented to the plasma discharge region 7, but changed in position relative to the plasma discharge region 7. For example, a wafer may be rotated on a disk about an axis of rotation 22 that passes through the wafer and/or the plasma discharge region 7 as shown in FIG. 3 and described in U.S. application Ser. No. 10/006,462, rather than about an axis of rotation that does not pass through the wafer or plasma discharge region 7 as is shown in FIGS. 1 and 2. In the illustrative embodiment of FIG. 3, a rotatably mounted workpiece support 2 may be arranged to support only one wafer relative to the plasma discharge region 7 of the plasma generating device. Alternately, the workpiece support 2 may have an arrangement such as that shown in FIG. 2 while having the capability to rotate each of the wafers about an axis that passes near each wafer's center. In this alternate arrangement, multiple wafers may be mounted to the workpiece support 2 which indexes through each of the wafers to implant the wafers one-at-a-time at the plasma discharge region 7. The wafer(s) may be rotated about an axis 22 that passes near the center of the wafer at any suitable speed, such as about 10 to 600 RPM. The rotational speed of the wafer may be selected so that if the plasma is pulsed, the pulse rate applied to the plasma is greater than the rotational speed and/or so that rotation of the wafer is not synchronized with the pulse rate. By rotating the wafer during an implantation process, azimuthal uniformity variations may be averaged over the wafer surface, thereby increasing dose uniformity.

In the illustrative embodiment of FIGS. 1 and 2, the wafers 4 on the disk of the workpiece support 2 may be rotated by the wafer drive controller 12 within the plasma implantation chamber 1 at a suitable rate, such as 1,000 RPM. As a result, each wafer 4 on the support 2 may be presented to the plasma for implantation approximately 1,000 times per minute. Voltage pulses applied by the plasma implant controller II to the electrode 5 and/or the workpiece support 2 to accelerate and implant ions in the plasma into the semiconductor wafers 4 may be adjusted in frequency and timing so that implantation occurs when the wafers 4 are suitably positioned relative to the plasma and ions are uniformly implanted in the semiconductor wafers 4 over the course of the implantation processing. In one illustrative embodiment, voltage pulses may be applied to the plasma at a rate of approximately 1500 pulses per second. Pulsing the plasma at a rate (frequency) greater than a rate at which the wafers 4 are presented to the plasma for implantation may compensate for non-uniformities in the implantation process. Thus, by pulsing the plasma at a relatively high rate compared to the rate at which wafers are presented to the plasma, pseudo-random portions of the wafers may be implanted with ions from the plasma for each pulse. By varying the portions of the wafers that are implanted for each pulse, non-uniformities in the system may be averaged out or otherwise compensated for to achieve overall uniformity in implantation of the wafers. Those of skill in the art will appreciate that the pulse rate and rotation of the wafers in some embodiments should be adjusted so that the pulsing is not improperly synchronized and the wafers are improperly implanted, e.g., so that one portion of a wafer is implanted with a larger dose than another portion of the wafer. However, it is also contemplated that the timing of pulses applied to the plasma (if used) may be synchronized with the angular position of wafers 4 and/or the workpiece support 2 so that the position of wafers 4 relative to the plasma or plasma discharge region 7 at each pulse may be better controlled. Of course, pulses need not be applied to the plasma to accelerate ions into the wafers, but instead other plasma implantation processes, such as a longer duration voltage applied to the plasma, may be used.

By moving the semiconductor wafer during implantation, temporal and/or spatial non-uniformities in the plasma, electric fields near the wafer 4 or other parameters that affect implantation may be averaged out over a particle implantation area of the wafer. For example, if during one period of implantation a portion of a wafer 4 receives a smaller dose density than other portions of the wafer 4, movement of the wafer 4 may result in that area receiving a higher dose density than other portions during a later implantation period. The precise mechanism by which movement of the semiconductor wafer may compensate for non-uniformity in the wafer dose may vary depending upon various implantation parameters, such as the size and/or shape of the plasma discharge region, the shape of electric fields generated near the wafer during implantation, or other areas. Thus, various movements or combination of movements of the semiconductor wafer 4 may be arranged to compensate for dose non-uniformities for a given plasma implantation arrangement. Movement of the wafer 4 may be adjusted or otherwise controlled based on a pre-programmed movement routine, and/or based on a feedback control arrangement. For example, a rotational speed of the disk carrying wafers may be adjusted to achieve a desired dose uniformity in the wafers or total dose delivered to the wafers. In a feedback control arrangement, Faraday cups or other sensors capable of providing an output representative of a dose being delivered to at least a portion of a wafer 4 may be used to adjust wafer movement and compensate for variations in the implantation parameters. Such sensors may be provided around or otherwise near the wafer 4 on the workpiece support 2, as shown in U.S. Pat. No. 6,020,592.

It should be understood that movement of the semiconductor wafer 4, as used herein, is relative to the plasma or plasma generating area, so movement of the semiconductor wafer is determined using the plasma or plasma discharge region as the reference point. Thus, a plasma implantation system may be arranged so that the plasma or plasma generating device moves relative to the semiconductor wafer 4 as viewed from outside the plasma implantation chamber 1. Accordingly, moving the semiconductor wafer 4 relative to the plasma or plasma discharge region 7 may include moving the semiconductor wafer 4 and/or moving the plasma or plasma discharge region 7 relative to a reference point outside the plasma implantation chamber 1.

It should be understood that as used herein, implanting ions from a plasma into a semiconductor wafer while the semiconductor moves is intended to refer at least to situations in which the wafer moves an appreciable distance during a period in which ions are actually being implanted into the wafer, as well as situations in which implantation or an implantation cycle is initiated while the wafer is moving. For example, in some plasma implantation systems, short duration pulses are applied to the plasma to accelerate ions in the plasma and implant them in the wafer. Due to the sometimes short duration of these pulses, the wafer may not actually move an appreciable distance during the time that ions are actually impacting the semiconductor wafer 4. However, as used herein, implanting ions from a plasma in a wafer while the wafer moves is intended to cover situations in which implantation is initiated, e.g., a pulse is first applied to a plasma, while the wafer is in motion. Likewise, the term implantation processing or an implantation process may include multiple implantation cycles where a plasma is pulsed with a voltage once for each cycle, and/or include one or more longer duration implantation cycles where the plasma is subjected to a longer duration or continuous voltage signal.

In another aspect of the invention, ions in a plasma may be implanted into an area of a semiconductor substrate, such as a semiconductor wafer, that is smaller than a particle implantation area of the substrate where ions are to be implanted. For example, a particle implantation area of a semiconductor wafer may include one entire face of the semiconductor wafer, or a portion of the face. In accordance with this aspect of the invention, only a portion of the entire particle implantation area may be implanted with ions from a plasma during a portion of an implantation process. Such partial implantation may be achieved in a number of different suitable ways, including generating a plasma in a plasma discharge region that is smaller than a particle implantation area of a semiconductor substrate, or exposing only a portion of a particle implantation area to a plasma for implantation.

For example, FIG. 2 shows a perspective view of the workpiece support having a plurality of semiconductor wafers mounted in a circular array to the support 2 as well as the electrode 5 and hollow pulse source 6. In this illustrative embodiment, the hollow pulse source 6 is sized to generate a plasma suitable for implanting the entire exposed surface of each semiconductor wafer 4. However, it should be understood that the plasma generating device may be differently sized or shaped. For example, although the plasma discharge region formed by the hollow pulse source 6 is approximately circular in this illustrative embodiment, the plasma discharge region may be rectangular, oval or otherwise suitably shaped. In addition, the plasma discharge region need not be as large as the particle implantation area on the semiconductor wafers 4. That is, the plasma discharge region may be smaller than the semiconductor wafers 4 and effectively scanned over the particle implantation area.

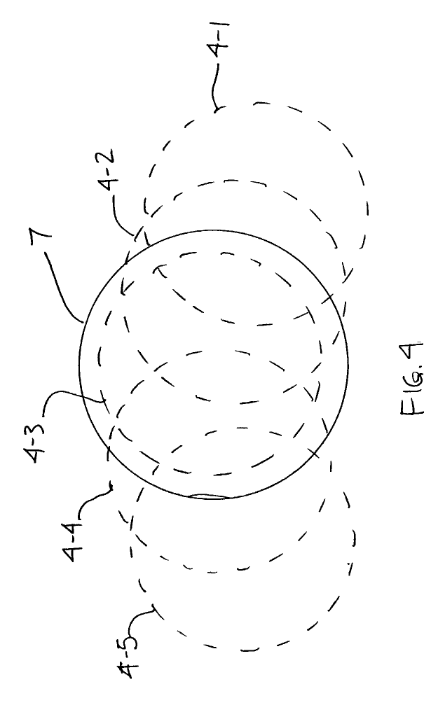

However the plasma discharge region is sized and/or shaped, the plasma implantation system 100 may operate so that only a portion of the particle implantation area of each semiconductor wafer 4 is implanted with ions from the plasma during a given period of an implantation process. For example, as shown in FIG. 4, as a wafer is rotated past the plasma discharge region 7 on the disk of FIG. 2, pulses may be applied to the plasma to implant different portions of the wafer. FIG. 4 illustrates five different positions of a wafer, 4-1 through 4-5, where a pulse is applied to the plasma and the wafer 4 is implanted. At position 4-1, a left portion of the wafer 4 presented to the plasma discharge region 7 is implanted based on a pulse corresponding to position 4-1. At position 4-2, a majority of the wafer 4 is presented to the plasma discharge region 7 and is implanted. At position 4-3, the entire wafer is presented to the plasma discharge region 7 and is implanted. At position 4-4, a left portion of the wafer 4 is not exposed to the plasma, and thus approximately the right half of the wafer 4 is implanted based on the pulse corresponding to position 4-4. At position 4-5, only the right portion of the wafer 4 presented to the plasma discharge region 7 is implanted for the pulse at position 4-5. Such an arrangement may allow for controlled non-uniformity in implantation, e.g., preferentially increasing a total dose for some portions of a wafer as compared to other portions of the wafer, or may allow for increased overall uniformity of implantation in the wafer.

It should be understood that aspects of the invention are not limited to the illustrative embodiment of FIG. 4. That is, the plasma need not be pulsed, but instead a longer duration voltage may be applied to the plasma as the wafer moves between two or more of the positions 4-1 to 4-5. Alternately, the plasma may be pulsed for other wafer positions than those shown, or only for certain positions shown in FIG. 4. For example, the plasma may be pulsed only once for each rotation of a wafer when the wafer is at a position corresponding to position 4-3 shown in FIG. 4. As discussed above, it is also contemplated that the wafers may be moved in a linear direction relative to the plasma discharge region 7, rather than an arcuate trajectory shown in FIG. 4.

In accordance with another aspect of the invention, a plurality of semiconductor substrates, such as semiconductor wafers, may be provided in a plasma implantation chamber for simultaneous processing. This is in contrast to conventional plasma implantation systems in which one wafer is provided in a plasma implantation chamber and implanted with ions from a plasma. By providing multiple semiconductor wafers in a chamber and simultaneously implantation processing the wafers, per wafer implant times can be reduced. The per wafer implantation processing times may be reduced because only one major evacuation of the plasma implantation chamber 1 may be required for a plurality of wafers. That is, in conventional plasma implantation systems, a single wafer is positioned in an implantation chamber at low pressure (relatively high vacuum) and the chamber is closed. The chamber is then filled with a suitable dopant gas, implantation is performed, and the gas in the chamber is pumped out to again establish a low pressure in the chamber. After evacuation of the chamber is complete, the implanted wafer is removed from the chamber and a next wafer for processing is placed in the chamber. The chamber is again filled with dopant gas, implantation is performed, the chamber evacuated, and the implanted wafer removed. In accordance with this aspect of the invention, only one major evacuation of the chamber and/or fill of the chamber with dopant gas may be required for a plurality of semiconductor wafers. Thus, the relatively long evacuation time may be spread over multiple wafers, thus reducing the per wafer processing time. Other efficiencies in the plasma implantation process may be realized by the simultaneous implantation processing of multiple wafers in a single implantation chamber.

While the invention has been described in conjunction with specific embodiments thereof, it is evident that many alternatives, modifications and variations will be apparent to those skilled in the art. Accordingly, preferred embodiments of the invention as set forth herein are intended to be illustrative, not limiting. Various changes may be made without departing from the spirit and scope of the invention.

1. A plasma implantation system comprising:
a plasma implantation chamber;
a workpiece support that moves at least one workpiece within the plasma implantation chamber;
a plasma generating device constructed and arranged to generate a plasma at or near a workpiece surface to implant ions in the at least one workpiece; and
a controller that causes the workpiece support to move the at least one workpiece within the plasma implantation chamber during an implantation process during which the controller causes the plasma generating device to generate a plasma and implant ions in the at least one workpiece.

2. The system of claim 1, wherein the controller includes a workpiece drive controller that moves at least a portion of the workpiece support in the plasma implantation chamber.

3. The system of claim 1, wherein the controller includes a plasma implant controller that controls the introduction of process gas and generation of an implantation plasma in the plasma implantation chamber.

4. The system of claim 1, wherein the workpiece support includes a disk, constructed and arranged to support a plurality of workpieces, that is mounted for rotation in the plasma implantation chamber.

5. The system of claim 4, wherein the disk supports the plurality of workpieces in a circular array on the disk.

6. The system of claim 4, wherein the workpiece support moves the workpieces in a circular path in the plasma implantation chamber.

7. The system of claim 4, wherein the workpiece support moves the workpieces in an arc-shaped trajectory relative to a region where the plasma generating device generates the plasma.

8. The system of claim 4, wherein the workpiece support is constructed and arranged to move the plurality of workpieces in a radial direction relative to rotation of the disk.

9. The system of claim 1, wherein the workpiece support is constructed and arranged to move the at least one workpiece to adjust a uniformity of ions implanted in the workpiece.

10. The system of claim 1, wherein the plasma generating device is constructed and arranged to generate a plasma suitable for implanting ions in only a portion of a workpiece on the workpiece support.

11. The system of claim 1, wherein the workpiece support is constructed and arranged to periodically present the at least one workpiece to the plasma for implantation, and the plasma generating device is constructed and arranged to apply pulses to a plasma to accelerate ions in the plasma to impact a workpiece, a rate at which pulses are applied to the plasma being greater than a rate at which the workpiece support presents the at least one workpiece to the plasma for implantation.

12. The system of claim 1, wherein the at least one workpiece includes a plurality of workpieces that are simultaneously processed in the plasma implantation chamber to implant the plurality of workpieces with ions from the plasma.

13. The system of claim 1, wherein the workpiece support is constructed and arranged to rotate the at least one workpiece about an axis that passes through the workpiece.

14. A method for implanting ions in a workpiece, comprising:
providing a plurality of workpieces within a plasma implantation chamber;
moving the plurality of workpieces in the plasma implantation chamber; and
implanting ions from a plasma located at or near a surface of at least one of the plurality of workpieces into the at least one of the plurality of workpieces while the at least one of the plurality of workpieces moves in the plasma implantation chamber.

15. The method of claim 14, wherein the step of moving the plurality of workpieces comprises moving the plurality of workpieces in a circular path in the plasma implantation chamber, the circular path having an axis of rotation.

16. The method of claim 15, wherein the axis of rotation does not pass through any one of the plurality of workpieces.

17. The method of claim 14, wherein the step of implanting ions comprises generating a plasma in a plasma discharge region that is smaller than a particle implantation area of each of the workpieces in which ions are implanted.

18. The method of claim 14, wherein the step of moving the plurality of workpieces comprises periodically presenting each of the plurality of workpieces to the plasma for particle implantation, and the step of implanting ions comprises pulsing the plasma with an electric field at a rate that exceeds a rate at which each of the plurality of workpieces is presented to the plasma for particle implantation.

19. The method of claim 14, wherein the step of moving the plurality of workpieces comprises adjusting a speed of the plurality of workpieces to adjust for variations in dose uniformity or a total dose provided to the plurality of workpieces.

20. A method for implanting ions in a semiconductor workpiece, comprising:
providing at least one workpiece in a plasma implantation chamber;
generating a plasma in a plasma discharge region located at or near a surface of the at least one workpiece in the plasma implantation chamber;
implanting ions in the plasma in the at least one workpiece while the at least one workpiece is in a first position relative to the plasma discharge region;
moving the at least one workpiece relative to the plasma discharge region without removing the at least one workpiece from the plasma implantation chamber; and
implanting ions from a plasma in the at least one workpiece while the at least one workpiece is in a second position relative to the plasma discharge region.

21. The method of claim 20, wherein the step of moving the at least one workpiece comprises moving the at least one workpiece in an arcuate path relative to the plasma discharge region.

22. The method of claim 20, wherein the step of generating a plasma comprises generating a plasma in a region that is smaller than a surface of the at least one workpiece in which ions are implanted.

23. The method of claim 20, wherein the step of providing at least one workpiece comprises mounting the at least one workpiece to a disk in the plasma implantation chamber, and the step of moving the at least one workpiece comprises rotating the disk to move the at least one workpiece relative to the plasma discharge region.

24. The method of claim 20, wherein the step of moving the at least one workpiece comprises periodically presenting the at least one workpiece to the plasma for implantation, and further comprising pulsing the plasma with an electric field at a rate that is greater than a rate at which the at least one workpiece is periodically presented to the plasma.

25. The method of claim 24, wherein the steps of implanting ions comprise implanting ions for a single pulse of the plasma in an area of the at least one workpiece that is smaller than an entire area of the at least one workpiece in which ions are to be implanted.

26. The method of claim 20, wherein the step of moving the at least one workpiece comprises moving the at least one workpiece in the plasma implantation chamber to improve uniformity of ions implanted in the at least one semiconductor wafer from the plasma.

27. The method of claim 20, wherein the step of providing at least one workpiece comprises mounting a plurality of semiconductor wafers to a disk in the plasma implantation chamber, and the step of moving the at least one workpiece comprises rotating the disk in the plasma implantation chamber with the plurality of semiconductor wafers mounted to the disk.

28. The method of claim 20, wherein the step of moving the at least one workpiece comprises rotating the at least one workpiece around an axis that passes through the at least one workpiece.

29. The method of claim 20, wherein the step of moving the at least one workpiece comprises adjusting movement of the at least one workpiece to improve dose uniformity or a total dose provided to the at least one workpiece.

30. A method for implanting ions in a semiconductor wafer, comprising:
providing at least one semiconductor wafer in a plasma implantation chamber, the at least one semiconductor wafer having a particle implantation area where ions are to be implanted;
generating a plasma located at or near a surface of the at least one semiconductor wafer in the plasma implantation chamber; and
implanting ions in the plasma in the at least one semiconductor wafer in an area of the at least one semiconductor wafer that is smaller than the particle implantation area of the wafer.

31. The method of claim 30, wherein the step of implanting ions comprises implanting ions in the at least one semiconductor wafer when the at least one semiconductor wafer is at a first position in the plasma implantation chamber; and further comprising implanting ions in the at least one semiconductor wafer when the at least one semiconductor wafer is in a second position in the plasma implantation chamber.
